(19) United States
(12) Patent Application Publication
(10) Pub. No.: US 2025/0112286 A1
(43) Pub. Date: Apr. 3, 2025

(54) CELL BALANCING METHOD AND BATTERY PACK EMPLOYING SAME

(71) Applicant: LG ENERGY SOLUTION, LTD., Seoul (KR)

(72) Inventors: Tae Cheol JEONG, Daejeon (KR); Seog Jin YOON, Daejeon (KR)

(73) Assignee: LG ENERGY SOLUTION, LTD., Seoul (KR)

(21) Appl. No.: 18/293,255

(22) PCT Filed: Dec. 27, 2022
(86) PCT No.: PCT/KR2022/021389

§ 371 Date: Jan. 29, 2024

(30) Foreign Application Priority Data
Apr. 27, 2022 (KR) 10-2022-0052179

(51) Int. Cl. H01M 10/44; H01M 10/42; H01M 10/48

(52) U.S. Cl. CPC H01M 10/441; H01M 10/425; H01M 10/486; H01M 2010/4271; H01M 2010/4278

(57) ABSTRACT

A cell balancing method is capable of increasing cell balancing efficiency by variably controlling a cell balancing switching pulse-width modulation (PWM) duty ratio depending on a cell balancing current, a battery management system (BMS temperature, and an operating mode. Further, a battery pack using the same cell balancing method is provided.

### TECHNICAL FIELD

The present invention relates to a cell balancing method and a battery pack with the same applied thereto, and more particularly, to a cell balancing method capable of increasing cell balancing efficiency by controlling a cell balancing switching pulse width modulation (PWM) duty, and to a battery pack with the same applied thereto.

### BACKGROUND ART

A battery pack mounted in a device requiring a chargeable electricity storage device, such as a portable electronic device, an electric vehicle, or an energy storage device, includes a plurality of battery cells connected in series or parallel.

Each battery cell included in the battery pack has a different capacity due to various reasons in the manufacturing process. Accordingly, in the battery pack, a voltage difference between the battery cells occurs during a charge/discharge cycle, and as the number of charge/discharge cycles increases, the voltage difference between the battery cells is also accumulated and increased. As the above situation is repeated, the lifespan of the battery pack is reduced. In order to solve the aforementioned problem, a cell balancing technology is applied to the battery pack to adjust the voltage difference between battery cells generated during charging/discharging.

The cell balancing technology is largely divided into active cell balancing and passive cell balancing, and in general, the passive balancing method is mainly used because of circuit configuration and low cost. The passive balancing method is a method in which, when the voltage of a specific battery cell or module is higher than a reference voltage (minimum battery cell or module voltage), the voltage is lowered to the level of the reference voltage by performing forced discharge through a cell balancing resistor. More specifically, a method of discharging a connection circuit between a discharge resistor and a battery cell through PWM switching control using a field-effect transistor (FET) is used. Here, the PWM switching is controlled with a predetermined PWM duty considering input values such as battery management system (BMS) temperature and cell voltage/current. In this case, when the voltage difference between battery cells or modules is large, it may take a long time to complete cell balancing, and thus, for example, when it is necessary to stabilize the voltage difference between battery cells or modules in a short time, it may be difficult to respond quickly, and good balancing efficiency is also difficult to expect. Examples of the related art include following documents.
KR 1459539 B1

### DISCLOSURE OF THE INVENTION

### Technical Problem

The present invention has been made to solve the above problems, and is to provide a cell balancing method capable of increasing cell balancing efficiency by variably controlling cell balancing switching PWM duty depending on a cell balancing current, a BMS temperature, and an operating mode, and a battery pack with the same applied.

### Technical Solution

According to an embodiment of the present invention, there is provided a method for cell balancing between at least two or more battery banks included in a battery pack, the method including: a battery information acquisition step of acquiring battery information including current, voltage, and temperature of a battery at regular intervals; a cell balancing necessity determination step of determining whether the cell balancing is necessary by using the battery information acquired in the battery information acquisition step; a cell balancing start step of turning on a cell balancing switch with an initial duty ratio and executing an initial cell balancing mode when the determination is made that the cell balancing is necessary in the cell balancing necessity determination step; a cell balancing switch duty ratio change determination step of determining whether a duty ratio of the cell balancing switch needs to be changed by using the acquired battery information after the cell balancing starts; a cell balancing switch duty ratio increase step of increasing the duty ratio of the cell balancing switch by a predetermined range when the determination is made that the duty ratio of the cell balancing switch needs to be changed in the cell balancing switch duty ratio change determination step; a cell balancing continuation determination step of determining whether to continue the cell balancing using the acquired battery information; a diagnosis count increase determination step of increasing the number of diagnosis counting when the determination is made that the cell balancing is to be continued in the cell balancing continuation determination step and the number of cell balancing cycles exceeds a predetermined reference number of cell balancing cycles; and a cell balancing mode change step of changing a cell balancing mode and returning to the cell balancing switch duty ratio change determination step when the number of diagnosis counting counted through the diagnosis count increase determination step is less than or equal to a predetermined reference number of diagnosis counting.

Further, the method may further include: a cell balancing end step of controlling the cell balancing switch to be turned off when the determination is made that the cell balancing is not to be continued in the cell balancing continuation determination step; and a diagnosis end step of reporting a diagnosis result and ending a procedure when the counted number of diagnosis counting exceeds the predetermined reference number of diagnosis counting through the diagnosis count increase determination step.

Meanwhile, the cell balancing necessity determination step may include determining that the cell balancing is necessary, when a bank voltage maximum difference value that is a difference between a maximum voltage and a minimum voltage among voltage values of the battery banks included in the acquired battery information exceeds a predetermined reference voltage difference value and a state of charge (SOC) is within a predetermined reference range.

Meanwhile, the cell balancing switch duty ratio change determination step may include: determining that the duty ratio of the cell balancing switch needs to be changed when a BMS temperature included in the acquired battery information is less than a predetermined reference temperature and a cell balancing current is less than a reference current; and determining that the duty ratio of the cell balancing switch does not need to be changed when any one of the BMS temperature and the cell balancing current does not satisfy a condition.

Meanwhile, the cell balancing continuation determination step may include: determining that cell balancing does not need to be continued, when a maximum bank voltage difference value that is a difference between a maximum voltage and a minimum voltage among voltage values of the battery banks included in the acquired battery information is less than or equal to a predetermined reference voltage difference; and determining that cell balancing needs to be continued when the bank voltage difference value exceeds a predetermined reference voltage difference value.

Here, the cell balancing mode may be one of a charging mode, a standby mode, and a discharging mode, and the cell balancing mode change step may include changing the cell balancing mode in an order of the charging mode, the standby mode, and the discharging mode.

According to an embodiment of the present invention, there is provided a battery pack including: at least two or more battery banks including a plurality of battery cells; a battery information measurement unit that measures battery information including current, voltage, temperature, and an SOC of a battery at regular intervals; a cell balancing necessity determination unit that determines whether cell balancing is necessary by using the battery information acquired from the battery information measurement unit; a duty ratio change determination unit that determines whether a duty ratio of a cell balancing switch needs to be changed by using the battery information acquired from the battery information measurement unit, after a cell balancing operation is activated by a result of the determination of the cell balancing necessity determination unit; a count unit that counts the number of cell balancing cycles and the number of diagnosis counting; a diagnosis count increase determination unit that determines whether to increase the number of diagnosis counting depending on whether the cell balancing needs to be continued and whether the number of cell balancing cycles exceeds a predetermined reference number of cell balancing cycles; and a cell balancing mode change determination unit that determines whether to change the cell balancing mode depending on whether the number of diagnosis counting counted by the count unit is less than or equal to a predetermined reference number of diagnosis counting.

Further, the battery pack may further include: a cell balancing control unit that activate a cell balancing operation with an initial cell balancing switch and in an initial cell balancing mode when the cell balancing necessity determination unit determines that the cell balancing is necessary, and then makes setting by changing each of the duty ratio of the cell balancing switch and the cell balancing mode depending on whether a predetermined condition is satisfied with a change in a battery state; and a cell balancing unit that includes a cell balancing switch connected to a positive electrode of each battery bank to consume voltage of the battery bank and a cell balancing switch for turning on and off a connection path between the cell balancing resistor and the battery bank.

Meanwhile, the cell balancing necessity determination unit may include: a voltage difference calculation unit that calculates a bank voltage difference that is a difference between a maximum voltage and a minimum voltage among voltage values of battery banks included in the battery information acquired from the battery information measurement unit; a voltage comparison unit that compares a bank voltage difference value calculated by the voltage difference calculation unit with a predetermined reference voltage difference value to determine whether the bank voltage difference value exceeds the predetermined reference voltage difference value, and outputs a signal corresponding to a result of the comparison; an SOC comparison unit that compares an SOC included in the battery information acquired from the battery information measurement unit with values of a predetermined reference SOC range to determine whether the SOC is within the predetermined reference SOC range, and outputs an SOC satisfaction signal when the SOC is within the predetermined reference SOC range; and a necessity determination unit that determines that the cell balancing is necessary when the calculated bank voltage difference value exceeds the predetermined reference voltage difference value and the SOC is within the predetermined reference SOC range.

More specifically, the voltage comparison unit may output a voltage-excess signal when the calculated bank voltage difference value exceeds the predetermined reference voltage difference value as the result of the comparison, and output a voltage-or-less signal when the calculated bank voltage difference value is less than or equal to the predetermined reference voltage difference value, and the necessity determination unit may determine that the cell balancing is necessary and outputs a balancing start signal, when both the voltage-excess signal and the SOC satisfaction signal are output.

Meanwhile, the necessity determination unit may determine that the cell balancing is not to be continued and output a balancing end signal, when the voltage-or-less signal is output from the voltage comparison unit after the balancing start signal is output; and determine that the cell balancing is to be continued and output a balancing continuation signal, when the voltage-excess signal is output from the voltage comparison unit after the balancing start signal is output.

Meanwhile, the duty ratio change determination unit may include: a temperature comparison unit that, after the balancing start signal is output from the necessity determination unit, compares a BMS temperature included the battery information acquired from the battery information measurement unit with a predetermined reference temperature to determine whether the BMS temperature is less than the predetermined reference temperature, and outputs a temperature satisfaction signal when the BMS temperature is less than the predetermined reference temperature; a current comparison unit that, after the balancing start signal is output from the necessity determination unit, compares a cell balancing current included the battery information acquired from the battery information measurement unit with a predetermined reference current to determine whether the cell balancing current is less than the predetermined reference current, and outputs a current satisfaction signal when the cell balancing current is less than the predetermined reference current; and a change determination unit that determines whether the duty ratio of the cell balancing switch of the cell balancing unit needs to be changed according to a result of comparisons of the temperature comparison unit and the current comparison unit.

More specifically, the change determination unit may determine that the duty ratio of the cell balancing switch needs to be changed and outputs a duty ratio change signal, when both the temperature satisfaction signal and the current satisfaction signal are output from the temperature comparison unit and the current comparison unit, and determine that the duty ratio of the cell balancing switch does not need to be changed when any one of the temperature satisfaction signal and the current satisfaction signal is not output from the temperature comparison unit and the current comparison unit.

Meanwhile, the count unit may include a cycle number count unit that, when the balancing start signal is output from the necessity determination unit of the cell balancing necessity determination unit, counts the number of cell balancing cycles from a point in time when the balancing start signal is output.

Meanwhile, the diagnosis count increase determination unit may include: a number comparison unit that compares the number of cell balancing cycles counted by the cycle number count unit of the count unit with the predetermined reference number of cell balancing cycles to determine whether the number of cell balancing cycles exceeds the predetermined reference number of cell balancing cycles, and outputs a cycle-number-excess signal when the number of cell balancing cycles exceeds the predetermined reference number of cell balancing cycles; and an increase determination unit that determines that the number of diagnosis counting is to be increased and outputs a diagnosis-counting-increase signal, when the balancing continuation signal is output from the necessity determination unit of the cell balancing necessity determination unit and the cycle-number-excess signal is output from the number comparison unit.

Meanwhile, the count unit may further include a number-of-diagnosis-counting count unit that increases the number of diagnosis counting when a diagnosis counting signal is output from the increase determination unit of the diagnosis count increase determination unit.

Meanwhile, the cell balancing mode change determination unit may determine that the cell balancing mode needs to be changed and outputs a mode change signal, when the number of diagnosis counting counted by the number-of-diagnosis-counting count unit is less than or equal to the reference number of diagnosis counting.

Meanwhile, the cell balancing control unit may include: a switch control unit that turns on the cell balancing switch of the cell balancing unit with the initial duty ratio when the balancing start signal is output from the necessity determination unit of the cell balancing necessity determination unit; and a cell balancing mode setting unit that sets the cell balancing mode to the initial cell balancing mode when the balancing start signal is output from the necessity determination unit of the cell balancing necessity determination unit.

Meanwhile, the switch control unit of the cell balancing control unit may turn on the cell balancing switch with the duty ratio of the cell balancing switch set to be increased by a predetermined range when the duty ratio change signal is output from the change determination unit of the duty ratio change determination unit, and turn off the cell balancing switch when the balancing end signal is output from the necessity determination unit of the cell balancing necessity determination unit.

Meanwhile, the cell balancing mode setting unit of the cell balancing control unit may make setting by changing the cell balancing mode when the mode change signal is output from the cell balancing mode change determination unit.

Here, the cell balancing mode may be one of a charging mode, a standby mode, and a discharging mode, and changing of the cell balancing mode may be set in an order of the charging mode, the standby mode, and the discharging mode.

### Advantageous Effects

According to the embodiments of the present invention, cell balancing is performed by variably controlling a cell balancing switch PWM duty depending on a cell balancing current, a BMS temperature, and an operating mode.

Therefore, even when the voltage difference between battery cells or modules is large, it is possible to stabilize the voltage difference in a short time, and to increase the cell balancing efficiency.

### BRIEF DESCRIPTION OF THE DRAWINGS

FIG. 1 is a flowchart illustrating a cell balancing method according to an embodiment of the present invention.

FIG. 2 is a diagram schematically illustrating an overall configuration of a battery pack according to an embodiment of the present invention.

FIGS. 3 to 7 are diagrams illustrating detailed configurations of each component.

### MODE FOR CARRYING OUT THE INVENTION

Hereinafter, exemplary embodiments of the present disclosure will be described in detail with reference to the accompanying drawings so that those skilled in the art may easily perform the present disclosure. However, the present disclosure may be implemented by various modifications and is not limited to the exemplary embodiments described herein. In the drawings, in order to clarify the present disclosure, parts that are not related to description are omitted and like reference numerals represent like elements throughout the specification.

Hereinafter, exemplary embodiments will be described in detail with reference to the drawings.

### 1. Cell Balancing Method According to the Present Invention

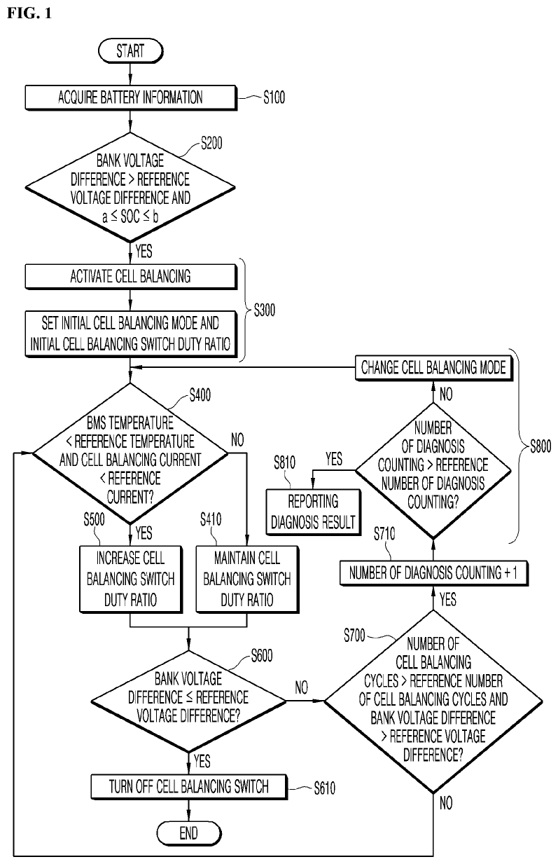

FIG. 1 is a flowchart illustrating a cell balancing method according to an embodiment of the present invention.

Referring to FIG. 1, the cell balancing method according to the present invention may include the following steps.

### 1.1. Battery Information Acquisition Step (S100)

A battery information acquisition step S100 is a step of acquiring battery information including current, voltage, temperature, state of charge (SOC), and the like, of a battery at regular intervals.

Here, the voltage of the battery may be a voltage value of each battery bank 100 composed of a plurality of battery cells (not shown).

In addition, the temperature of the battery may be a BMS temperature value obtained by measuring the temperature of a resistor, an FET, and the like, connected to a battery monitoring integrated circuit (BMIC).

### 1.2. Cell Balancing Necessity Determination Step (S200)

A cell balancing necessity determination step S200 is a step of determining whether cell balancing is necessary by using the battery information acquired in the battery information acquisition step S100.

More specifically, when a bank voltage difference value, which is the difference between a maximum voltage value and a minimum voltage value among voltage values of the battery banks included in the acquired battery information, exceeds a reference voltage difference and the SOC is within a predetermined reference range, the determination is made that cell balancing is necessary.

### 1.3. Cell Balancing Start Step (S300)

A cell balancing start step S300 is a step of activating cell balancing by setting a cell balancing switch (not shown) to an initial duty ratio and turning on the cell balancing switch, and executing an initial cell balancing mode, when the determination is made that cell balancing is necessary in the cell balancing necessity determination step S200.

Here, the initial duty ratio may be set to 20%, for example.

The cell balancing mode may be set to a charging mode, a standby mode, and a discharging mode.

In this case, when cell balancing is started, the cell balancing time may be counted from that point in time.

### 1.4. Cell Balancing Switch Duty Ratio Change Determination Step (S400)

A cell balancing switch duty ratio change determination step S400 is a step of determining whether a duty ratio of the cell balancing switch needs to be changed by using the BMS temperature and the cell balancing current included in the battery information acquired through the battery information acquisition step S100.

Specifically, when both conditions that the BMS temperature is less than a reference temperature and the cell balancing current is less than the reference cell balancing current through comparison of the cell balancing current with the reference cell balancing current are satisfied, the determination may be made that the duty ratio of the cell balancing switch needs to be changed.

On the other hand, when the BMS temperature is not less than the reference temperature or the cell balancing current is not less than the reference cell balancing current, that is, when any one of the BMS temperature and the cell balancing current does not satisfy the conditions, the determination may be made that the duty ratio of the cell balancing switch does not need to be changed. In this case, the initial duty ratio and the initial cell balancing mode set in the cell balancing start step S300 are maintained (S410).

### 1.5. Cell Balancing Switch Duty Ratio Increase Step (S500)

A cell balancing switch duty ratio increase step S500 is a step of operating when the determination is made that the duty ratio of the cell balancing switch needs to be changed in the cell balancing switch duty ratio change determination step S400.

When the determination is made that the duty ratio of the cell balancing switch needs to be changed, the duty ratio of the cell balancing switch is increased by a predetermined range increment.

For example, assuming that the duty ratio of the initial cell balancing switch in the cell balancing start step S300 is “A” and the predetermined range increment is “a”, the duty ratio of the cell balancing switch is increased to “A+a”.

In this way, when the BMS temperature and cell balancing current do not satisfy certain conditions even though the cell balancing operation is executed with the initial duty ratio of the cell balancing switch and cell balancing mode, it is possible to increase cell balancing efficiency by stepwise increasing the duty ratio of the cell balancing switch.

Meanwhile, the increment “a” of the duty ratio of the cell balancing switch may be allowed the cell balancing operating range to be set to be larger in the order of the charging mode, the standby mode, and the discharging mode, thereby increasing the duty ratio of the switch with the cell balancing mode.

### 1.6. Cell Balancing Continuation Determination Step (S600)

A cell balancing continuation determination step S600 is a step of determining whether to continue cell balancing current in operation by using the battery information acquired through the battery information acquisition step S100.

More specifically, when a bank voltage difference value, which is the difference between a maximum voltage value and a minimum voltage value among voltage values of the battery banks included in the acquired battery information, exceeds a reference voltage difference, the determination is made that cell balancing in operation needs to be continued.

On the other hand, when the bank voltage difference value is less than or equal to the reference voltage difference, the determination is made that cell balancing in operation does not need to be continued, and a cell balancing end step (S610) of turning off the cell balancing switch is performed.

### 1.7. Diagnosis Count Increase Determination Step (S700)

A diagnosis count increase determination step S700 is a step of determining whether to increase the number of diagnosis counting according to a result of the determination of whether to continue cell balancing in the cell balancing continuation determination step S600 and a result of comparing the number of cell balancing cycles with the reference number of cell balancing cycles.

Specifically, when the determination is made that the cell balancing needs to be continued and the number of cell balancing cycles is less than or equal to a predetermined reference number of cell balancing cycles, the determination is made that an increase in the diagnosis count is not necessary and return to the cell balancing switch duty ratio change determination step S400 is performed. On the other hand, at this time, when the determination is made that cell balancing does not need to be continued although cell balancing is continued for the predetermined number of cell balancing cycles or for the cell balancing time, that is, when the bank voltage difference value does not exceed the reference voltage difference and falls within the predetermined reference range, the cell balancing mode may be changed in a method different from a cell balancing mode change step S800, which will be described below, before returning to cell balancing switch duty ratio change determination step S400. At this time, the cell balancing mode may be changed in the order of the discharging mode, the standby mode, and the charging mode, so that the increment of the duty ratio of the cell balancing switch may be reduced. In this case, when the mode before the change is the charging mode, the charging mode is maintained.

On the other hand, when the determination is made that the cell balancing needs to be continued and the number of cell balancing cycles exceeds the predetermined reference number of cell balancing cycles, a determination is made that the diagnosis count is to be increased and the number of diagnosis counting is increased (S710). That is, when the bank voltage difference value, which is the difference between the maximum voltage value and the minimum voltage value among the voltage values of the battery banks, exceeds the reference voltage difference in spite of performing cell balancing by a predetermined reference number of cell balancing or for a predetermined reference cell balancing time, the number of diagnosis counting is increased.

Meanwhile, in determining whether to increase the diagnosis count, it has been described that the number of cell balancing cycles is used in one embodiment, but the cell balancing operating time may be used in another embodiment. In this case, for example, a result of the determination of whether the cell balancing operating time is less than or equal to or exceeds a predetermined reference cell balancing operating time may be reflected in determining whether to increase the diagnosis count.

### 1.8. Cell Balancing Mode Change Step (S800)

In a cell balancing mode change step S800, the cell balancing mode may be changed in the cell balancing start step S300 depending on whether the number of diagnosis counting counted through the diagnosis count increase determination step S700 is less than or equal to a predetermined reference number of diagnosis counting.

Specifically, when the number of diagnosis counting is less than or equal to the predetermined reference number of diagnosis counting, the cell balancing mode is changed, and return to the cell balancing switch duty ratio change determination step S400 is performed.

Here, the cell balancing mode may be one of the charging mode, the standby mode, and the discharging mode, and the cell balancing mode may be changed in the order of the charging mode, the standby mode, and the discharging mode. For example, when the initial cell balancing mode is the charging mode, the cell balancing mode may be changed to the standby mode in the cell balancing mode change step S800. When the cell balancing mode is the discharge mode before the change, the discharge mode is maintained.

Depending on the condition of the case in which the bank voltage difference is not decreased even though cell balancing is performed for the predetermined number of cell balancing or cell balancing time in the diagnosis count increase determination step S700, the cell balancing mode is changed in the order of the charging mode, the standby mode and the discharging mode and cell balancing is continued, thereby making it possible to obtain a larger increment of the increment of the duty ratio of the cell balancing switch.

However, when the number of diagnosis counting exceeds the predetermined reference number of diagnosis counting, cell balancing is not performed any more, a diagnosis result is reported, and a diagnosis end step S810 of ending the procedure is performed.

### 2. Battery Pack According to the Present Invention

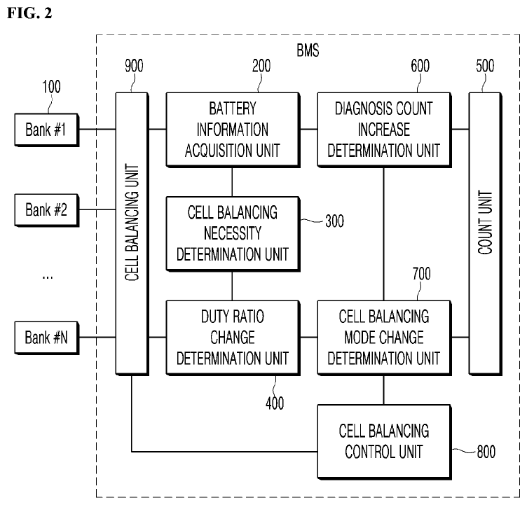

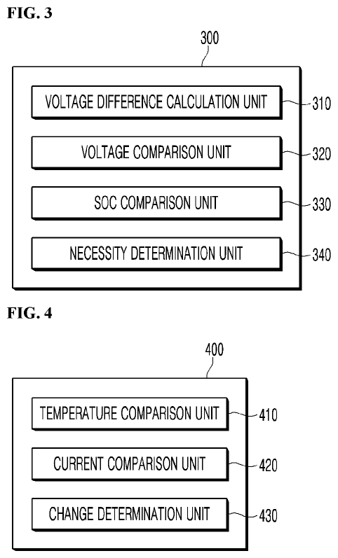

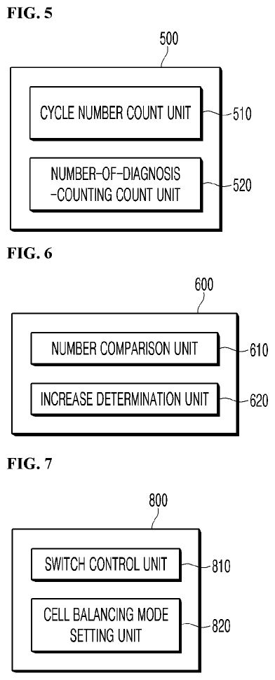

FIG. 2 is a diagram schematically illustrating an overall configuration of a battery pack according to an embodiment of the present invention.

Referring to FIG. 2, the battery pack of the present invention includes the following components.

### 2.1. Battery Bank (100)

As Shown in FIG. 2, the Battery Pack of the Present Invention Includes at Least Two or more battery banks 100 including a plurality of battery cells (not shown).
2.2. Battery information measurement unit (200)

A battery information measurement unit 200 is a component that measures battery information including current, voltage, temperature, an SOC, and the like, of a battery at regular intervals.

Here, the voltage may be a voltage value for each battery bank. The voltage of the battery bank may be obtained, for example, by a method of measuring the voltage of each battery cell and measuring/calculating based on the voltage values of the measured battery cells.

Meanwhile, the temperature may be a BMS temperature value. The BMS temperature may be obtained by measuring the temperature of a resistor or FET connected to BMIC), for example.

Meanwhile, the current may be a cell balancing current value.

As a method of measuring battery information including current, voltage, temperature, and SOC of the battery, a known method may be used.

### 2.3. Cell Balancing Necessity Determination Unit (300)

A cell balancing necessity determination unit 300 is a component that determines whether cell balancing of the battery is necessary by using the battery information acquired from the battery information measurement unit 200. The cell balancing necessity determination unit 300 may include the following sub-components.

### 2.3.1. Voltage Difference Calculation Unit (310)

A voltage difference calculation unit 310 is a component that calculates a bank voltage difference value, which is a difference between a maximum voltage value and a minimum voltage value among voltage values of battery banks included in the battery information acquired from the battery information measurement unit 200.

### 2.3.2. Voltage Comparison Unit (320)

A voltage comparison unit 320 is a component that compares a bank voltage difference value calculated by the voltage difference calculation unit 310 with a predetermined reference voltage difference value to determine whether the bank voltage difference value exceeds the predetermined reference voltage difference value, and outputs a signal corresponding to a result of the comparison.

More specifically, when the calculated bank voltage difference value exceeds the predetermined reference voltage difference value as the result of the comparison, the voltage comparison unit 320 may output a voltage-excess signal indicating it.

On the other hand, when the calculated bank voltage difference value is less than or equal to the predetermined reference voltage difference value as the result of the comparison, the voltage comparison unit 320 may output a voltage-or-less signal indicating it.

### 2.3.3. SOC Comparison Unit (330)

An SOC comparison unit 330 may compare an SOC included in the battery information acquired from the battery information measurement unit 200 with values of a predetermined reference SOC range to determine whether the SOC is within the predetermined reference SOC range, and when the SOC is within the predetermined reference SOC range, may output, for example, an SOC satisfaction signal indicating it.

### 2.3.4. Necessity Determination Unit (340)

A necessity determination unit 340 is a component that determines whether cell balancing is necessary according to a result of the comparisons of the voltage comparison unit 320 and the SOC comparison unit 330.

More specifically, the necessity determination unit 340 determines that the cell balancing is necessary when the calculated bank voltage difference value exceeds the predetermined reference voltage difference value and the SOC is within the predetermined reference SOC range.

That is, when the voltage-excess signal is output from the voltage comparison unit 320 and the SOC satisfaction signal is all output from the SOC comparison unit 330, the necessity determination unit 340 may determine that the cell balancing is necessary, and may, for example, output a balancing start signal indicating it.

On the other hand, the necessity determination unit 340 determines that cell balancing does not need to be continued when the voltage-or-less signal is output from the voltage comparison unit 320 after the cell balancing starts (after the balancing start signal is output), and may, for example, output a balancing end signal indicating it.

On the other hand, when the voltage-excess signal is output from the voltage comparison unit 320 after the cell balancing starts (after the balancing start signal is output), the necessity determination unit 340 determines that cell balancing needs to be continued, and, may, for example, output a balancing continuation signal indicating it.

### 2.4. Duty Ratio Change Determination Unit (400)

A duty ratio change determination unit 400 is a component that determines whether a duty ratio of the cell balancing switch (not shown) of a cell balancing unit 900 needs to be changed by using the battery information acquired from the battery information measurement unit 200, after a cell balancing operation is activated by a result of the determination of the cell balancing necessity determination unit 300.

The duty ratio change determination unit 400 may include the following sub-components.

### 2.4.1. Temperature Comparison Unit (410)

A temperature comparison unit 410 may compare the BMS temperature included in the battery information acquired from the battery information measurement unit 200 with a predetermined reference temperature to determine whether the BMS temperature is less than the predetermined reference temperature, after cell balancing is activated (after the balancing start signal is output), and when the BMS temperature is less than the predetermined reference temperature, may, for example, output a temperature satisfaction signal indicating it.

### 2.4.2. Current Comparison Unit (420)

A current comparison unit 420 may compare the cell balancing current included in the battery information acquired from the battery information measurement unit 200 with a predetermined reference current to determine whether the cell balancing current is less than the predetermined reference current, after cell balancing is activated (after the balancing start signal is output), and when the BMS temperature is less than the predetermined reference current, may, for example, output a current satisfaction signal indicating it.

### 2.4.3. Change Determination Unit (430)

A change determination unit 430 is a component that determines whether the duty ratio of the cell balancing switch (not shown) needs to be changed according to a result of comparisons of the temperature comparison unit 410 and the current comparison unit 420.

More specifically, when the BMS temperature is less than the predetermined reference temperature and the cell balancing current is less than the predetermined reference current, that is, when both the temperature satisfaction signal and the current satisfaction signal are output from the temperature comparison unit 410 and the current comparison unit 420, the change determination unit 430 determines that the duty ratio of the cell balancing switch needs to be changed. In this case, for example, a duty ratio change signal indicating it may be output.

On the other hand, the change determination unit 430 may determine that the duty ratio of the cell balancing switch does not need to be changed when any one of the temperature satisfaction signal and the current satisfaction signal is not output from the temperature comparison unit 410 and the current comparison unit 420.

### 2.5. Count Unit (500)

A count unit 500 is a component that counts the number of cell balancing cycles and the number of diagnosis counting.

### 2.5.1. Cycle Number Count Unit (510)

A cycle number count unit 510 is a component that counts the number of cell balancing cycles when cell balancing is activated according to a result of the determination of the cell balancing necessity determination unit 300. More specifically, when a balancing start signal is output from the necessity determination unit 340 of the cell balancing necessity determination unit 300, the cycle number count unit 510 may be provided in the form of counting the number of cell balancing cycles from that point in time.

Meanwhile, as another embodiment of the cycle number count unit 510, a balancing time count unit that counts the cell balancing operating time may also be provided. In this case, for example, when a balancing start signal is output from the necessity determination unit 340 of the cell balancing necessity determination unit 300, the cycle number count unit 510 may be provided in the form of counting the cell balancing operating time from that point in time.

### 2.5.2. Number-of-Diagnosis-Counting Count Unit (520)

A number-of diagnosis-counting count unit 520 is a component that increases the number of diagnosis counting when a determination is made that an increase in the number of diagnosis counting is necessary as a result of determination of a diagnosis count increase determination unit 600, which will be described later.

More specifically, when the diagnosis counting increase signal is output from the diagnosis count increase determination unit 600, the number of diagnosis counting may be increased by +1.

### 2.6. Diagnosis Count Increase Determination Unit (600)

The diagnosis count increase determination unit 600 is a component that determines whether to increase the number of diagnosis counting depending on whether cell balancing needs to be continued and whether the number of cell balancing cycles (or cell balancing operating time) exceeds a predetermined reference number of cell balancing cycles (or cell balancing operating time).

The diagnosis count increase determination unit 600 may include the following sub-components.

### 2.6.1. Number Comparison Unit (610)

A number comparison unit 610 is a component that compares the number of cell balancing cycles counted by the cycle number count unit 510 of the count unit 500 with a predetermined reference number of cell balancing cycles, and outputs a signal corresponding to a result of the comparison.

More specifically, when the counted number of cell balancing cycles is less than or equal to the reference number of cell balancing cycles, the number comparison unit 610 may output, for example, a number-of-cycles-or-less signal indicating it.

On the other hand, when the counted number of cell balancing cycles exceeds the reference number of cell balancing cycles, the number comparison unit 610 may output, for example, a number-of-cycles-excess signal indicating it.

### 2.6.2. Increase Determination Unit (620)

An increase determination unit 620 is a component that determines the increase in the number of diagnosis counting, depending on the result of the comparison of the number comparison unit 610 and the result of the determination of whether cell balancing is to be continued by the cell balancing necessity determination unit 300.

More specifically, when the determination is made that cell balancing is to be continued and the number of cell balancing cycles (or cell balancing operating time) is less than or equal to the predetermined reference number of cell balancing cycles (or cell balancing operating time), the increase determination unit 620 determines that the number of diagnosis counting is not to be increased.

On the other hand, when the determination is made that cell balancing is to be continued and the number of cell balancing cycles (or cell balancing operating time) exceeds the predetermined reference number of cell balancing cycles (or cell balancing operating time), the increase determination unit 620 determines that the number of diagnosis counting is to be increased.

In other words, when the balancing continuation signal is output from the necessity determination unit 340 of the cell balancing necessity determination unit 300 and the cycle-number-or-less signal is output from the number comparison unit 610, the increase determination unit 620 may determine that the number of diagnosis counting is not to be increased and may, for example, output a diagnosis-counting-non-increase signal indicating it.

On the other hand, when the balancing continuation signal is output from the necessity determination unit 340 of the cell balancing necessity determination unit 300 and the cycle-number-excess signal is output from the number comparison unit 610, the increase determination unit 620 may determine that the number of diagnosis counting is to be increased and may, for example, output a diagnosis-counting-increase signal indicating it.

### 2.7. Cell Balancing Mode Change Determination Unit (700)

A cell balancing mode change determination unit 700 is a component that determines whether to change the cell balancing mode depending on whether the number of diagnosis counting counted by the number-of-diagnosis-counting count unit 520 of the count unit 500 is less than or equal to a predetermined reference number of diagnosis counting.

More specifically, when the number of diagnosis counting counted by the number-of-diagnosis-counting count unit 520 is less than or equal to the reference number of diagnosis counting, the cell balancing mode change determination unit 700 may determine that the cell balancing mode needs to be changed, and may, for example, output a mode change signal indicating it.

On the other hand, when the number of diagnosis counting counted by the number-of-diagnosis-counting count unit 520 exceeds the reference number of diagnosis counting, the cell balancing mode change determination unit 700 may determine that the cell balancing mode does not need to be changed, and may, for example, output a mode non-change signal indicating it.

### 2.8. Cell Balancing Control Unit (800)

A cell balancing control unit 800 is a component that controls the cell balancing operation of the cell balancing unit 900 according to the result of the determination of the cell balancing necessity determination unit 300.

More specifically, the cell balancing control unit is configured to control the cell balancing operation by activating a cell balancing operation with an initial duty ratio of the cell balancing switch and in an initial cell balancing mode when the cell balancing necessity determination unit 300 determines that the cell balancing is necessary, and then making setting by changing each of the duty ratio and the cell balancing mode depending on whether a condition is satisfied with a change in a battery state.

### 2.8.1. Switch Control Unit (810)

A switch control unit 810 turns on a cell balancing switch (not shown) of the cell balancing unit 900 with the initial duty ratio when the balancing start signal is output from the necessity determination unit 340 of the cell balancing necessity determination unit 300.

Here, the duty ratio of the cell balancing switch may be set to 20%, for example.

Then, the switch control unit 810 may turn on the cell balancing switch with the duty ratio of the cell balancing switch (not shown) set to be increased by a predetermined range when the duty ratio change signal is output from the change determination unit 430 of the duty ratio change determination unit 400.

Meanwhile, then, the switch control unit 810 may end the cell balancing operation by controlling the cell balancing switch (not shown) to be turned off, when the balancing end signal is output from the necessity determination unit 340 of the cell balancing necessity determination unit 300.

### 2.8.2. Cell Balancing Mode Setting Unit (820)

A cell balancing mode setting unit 820 sets the cell balancing mode to the initial cell balancing mode when the balancing start signal is output from the necessity determination unit 340 of the cell balancing necessity determination unit 300. Then, the cell balancing mode setting unit 820 may change and set the cell balancing mode in a predetermined order when the mode change signal is output from the cell balancing mode change determination unit 400.

Here, the cell balancing mode may be one of a charging mode, a standby mode, and a discharging mode.

In addition, a predetermined cell balancing mode change order may be set in the order of the charging mode, the standby mode, and the discharging mode.

For example, when the initial cell balancing mode is the charging mode, the cell balancing mode, which is changed to make setting, as the mode change signal is output from the cell balancing mode change determination unit 400, is switched to the standby mode.

### 2.9. Cell Balancing Unit (900)

The cell balancing unit 900 is a component that includes a cell balancing resistor (not shown) connected to a positive electrode of each battery bank 100 to consume voltage of the battery bank and a cell balancing switch (not shown) for turning on and off a connection path between the cell balancing resistor (not shown) and the battery bank 100 to control the voltage difference between the battery banks 100 by performing the cell balancing operation under the control of the cell balancing control unit 800.

Meanwhile, although the technical spirit of the present invention has been specifically described according to the above embodiments, it should be noted that the above embodiments are for explanation and not for limitation. In addition, those skilled in the art will understand that various embodiments are possible within the scope of the technical spirit of the present invention.

Symbols and names of the reference signs used in and drawings of the present invention are as follows.
100: Battery bank
200: Battery information measurement unit
300: Cell balancing necessity determination unit
310: Voltage difference calculation unit
320: Voltage comparison unit
330: SOC comparison unit
340: Necessity determination unit
400: Duty ratio change determination unit
410: Temperature comparison unit
420: Current comparison unit
430: Change determination unit
500: Count unit
510: Cycle number count unit
520: Number-of-diagnosis-counting count unit
600: Diagnosis count increase determination unit
610: Number comparison unit
620: Increase determination unit
700: Cell balancing mode change determination unit
800: Cell balancing control unit
810: Switch control unit
820: Cell balancing mode setting unit
900: Cell balancing unit

The invention claimed is:

1. A method for cell balancing between at least two or more battery banks included in a battery pack, the method comprising:
a battery information acquisition step of acquiring battery information including current, voltage, and temperature of a each battery bank at regular intervals;
a cell balancing necessity determination step of determining whether the cell balancing is necessary by using the battery information acquired in the battery information acquisition step;
a cell balancing start step of turning on a cell balancing switch with an initial duty ratio and executing an initial cell balancing mode when the determination is made that the cell balancing is necessary in the cell balancing necessity determination step;
a cell balancing switch duty ratio change determination step of determining whether a duty ratio of the cell balancing switch needs to be changed by using the acquired battery information after the cell balancing starts;
a cell balancing switch duty ratio increase step of increasing the duty ratio of the cell balancing switch by a predetermined range when the determination is made that the duty ratio of the cell balancing switch needs to be changed in the cell balancing switch duty ratio change determination step;
a cell balancing continuation determination step of determining whether to continue the cell balancing using the acquired battery information;
a diagnosis count increase determination step of increasing a number of diagnosis counting when the determination is made that the cell balancing is to be continued in the cell balancing continuation determination step and a number of cell balancing cycles exceeds a predetermined reference number of cell balancing cycles; and
a cell balancing mode change step of changing a cell balancing mode and returning to the cell balancing switch duty ratio change determination step when the number of diagnosis counting counted through the diagnosis count increase determination step is less than or equal to a predetermined reference number of diagnosis counting.

2. The method of claim 1, further comprising:
a cell balancing end step of controlling the cell balancing switch to be turned off when the determination is made that the cell balancing is not to be continued in the cell balancing continuation determination step; and
a diagnosis end step of reporting a diagnosis result and ending a procedure when the counted number of diagnosis counting exceeds the predetermined reference number of diagnosis counting through the diagnosis count increase determination step.

3. The method of claim 1, wherein the cell balancing necessity determination step comprises determining that the cell balancing is necessary, when a bank voltage difference value that is a difference between a maximum voltage and a minimum voltage among voltage values of the battery banks included in the acquired battery information exceeds a predetermined reference voltage difference value and a state of charge (SOC) is within a predetermined reference range.

4. The method of claim 1, wherein the cell balancing switch duty ratio change determination step comprises:
determining that the duty ratio of the cell balancing switch needs to be changed when a BMS-battery management system (BMS) temperature included in the acquired battery information is less than a predetermined reference temperature and a cell balancing current is less than a reference current; and
determining that the duty ratio of the cell balancing switch does not need to be changed when any one of the BMS temperature and the cell balancing current does not satisfy a condition.

5. The method of claim 1, wherein the cell balancing continuation determination step comprises:
determining that the cell balancing does not need to be continued, when a bank voltage difference value that is a difference between a maximum voltage and a minimum voltage among voltage values of the battery banks included in the acquired battery information is less than or equal to a predetermined reference voltage difference; and
determining that the cell balancing needs to be continued when the bank voltage difference value exceeds the predetermined reference voltage difference value.

6. The method of claim 1, wherein the cell balancing mode is one of a charging mode, a standby mode, and a discharging mode, and
the cell balancing mode change step comprises changing the cell balancing mode in an order of the charging mode, the standby mode, and the discharging mode.

7. A battery pack comprising:
at least two or more battery banks including a plurality of battery cells;
a battery information measurement unit that measures battery information including current, voltage, temperature, and state of charge (SOC) of each battery bank at regular intervals;
a cell balancing necessity determination unit that determines whether cell balancing is necessary by using the battery information acquired from the battery information measurement unit;
a duty ratio change determination unit that determines whether a duty ratio of a cell balancing switch needs to be changed by using the battery information acquired from the battery information measurement unit, after a cell balancing operation is activated by a result of the determination of the cell balancing necessity determination unit;
a count unit that counts a number of cell balancing cycles and a number of diagnosis counting;
a diagnosis count increase determination unit that determines whether to increase the number of diagnosis counting depending on whether the cell balancing needs to be continued and whether the number of cell balancing cycles exceeds a predetermined reference number of cell balancing cycles; and
a cell balancing mode change determination unit that determines whether to change the cell balancing mode depending on whether the number of diagnosis counting counted by the count unit is less than or equal to a predetermined reference number of diagnosis counting.

8. The battery pack of claim 7, further comprising:
a cell balancing control unit that activates a cell balancing operation with an initial cell balancing switch and in an initial cell balancing mode when the cell balancing necessity determination unit determines that the cell balancing is necessary, and then changes each of the duty ratio of the cell balancing switch and the cell balancing mode, depending on whether a predetermined condition is satisfied with a change in a battery state; and
a cell balancing unit that includes a cell balancing resistor connected to a positive electrode of each battery bank to consume voltage of the battery bank and a cell balancing switch for turning on and off a connection path between the cell balancing resistor and the battery bank.

9. The battery pack of claim 8, wherein the cell balancing necessity determination unit comprises:
a voltage difference calculation unit that calculates a bank voltage difference value that is a difference between a maximum voltage and a minimum voltage among voltage values of battery banks included in the battery information acquired from the battery information measurement unit;
a voltage comparison unit that compares the bank voltage difference value calculated by the voltage difference calculation unit with a predetermined reference voltage difference value to determine whether the bank voltage difference value exceeds the predetermined reference voltage difference value, and outputs a signal corresponding to a result of the comparison;
an SOC comparison unit that compares the SOC included in the battery information acquired from the battery information measurement unit with values of a predetermined reference SOC range to determine whether the SOC is within the predetermined reference SOC range, and outputs an SOC satisfaction signal when the SOC is within the predetermined reference SOC range; and
a necessity determination unit that determines that the cell balancing is necessary when the calculated bank voltage difference value exceeds the predetermined reference voltage difference value and the SOC is within the predetermined reference SOC range.

10. The battery pack of claim 9, wherein the voltage comparison unit outputs a voltage-excess signal when the calculated bank voltage difference value exceeds the predetermined reference voltage difference value as the result of the comparison, and outputs a voltage-or-less signal when the calculated bank voltage difference value is less than or equal to the predetermined reference voltage difference value, and
the necessity determination unit determines that the cell balancing is necessary and outputs a balancing start signal, when both the voltage-excess signal and the SOC satisfaction signal are output.

11. The battery pack of claim 10, wherein the necessity determination unit determines that the cell balancing is not to be continued and outputs a balancing end signal, when the voltage-or-less signal is output from the voltage comparison unit after the balancing start signal is output, and
determines that the cell balancing is to be continued and outputs a balancing continuation signal, when the voltage-excess signal is output from the voltage comparison unit after the balancing start signal is output.

12. The battery pack of claim 11, wherein the duty ratio change determination unit comprises:
a temperature comparison unit that, after the balancing start signal is output from the necessity determination unit, compares a battery management system (BMS) temperature included the battery information acquired from the battery information measurement unit with a predetermined reference temperature to determine whether the BMS temperature is less than the predetermined reference temperature, and outputs a temperature satisfaction signal when the BMS temperature is less than the predetermined reference temperature;
a current comparison unit that, after the balancing start signal is output from the necessity determination unit, compares a cell balancing current included the battery information acquired from the battery information measurement unit with a predetermined reference current to determine whether the cell balancing current is less than the predetermined reference current, and outputs a current satisfaction signal when the cell balancing current is less than the predetermined reference current; and
a change determination unit that determines whether the duty ratio of the cell balancing switch of the cell balancing unit needs to be changed according to a result of comparisons of the temperature comparison unit and the current comparison unit.

13. The battery pack of claim 12, wherein the change determination unit
determines that the duty ratio of the cell balancing switch needs to be changed and outputs a duty ratio change signal, when both the temperature satisfaction signal and the current satisfaction signal are output from the temperature comparison unit and the current comparison unit, respectively; and
determines that the duty ratio of the cell balancing switch does not need to be changed when any one of the temperature satisfaction signal and the current satisfaction signal is not output from the temperature comparison unit and the current comparison unit, respectively.

14. The battery pack of claim 11, wherein the count unit comprises a cycle number count unit that, when the balancing start signal is output from the necessity determination unit of the cell balancing necessity determination unit, counts the number of cell balancing cycles from a point in time when the balancing start signal is output.

15. The battery pack of claim 14, wherein the diagnosis count increase determination unit comprises:
a number comparison unit that compares the number of cell balancing cycles counted by the cycle number count unit of the count unit with the predetermined reference number of cell balancing cycles to determine whether the number of cell balancing cycles exceeds the predetermined reference number of cell balancing cycles, and outputs a cycle-number-excess signal when the number of cell balancing cycles exceeds the predetermined reference number of cell balancing cycles; and
an increase determination unit that determines that the number of diagnosis counting is to be increased and outputs a diagnosis-counting-increase signal, when the balancing continuation signal is output from the necessity determination unit of the cell balancing necessity determination unit and the cycle-number-excess signal is output from the number comparison unit.

16. The battery pack of claim 15, wherein the count unit further comprises a number-of-diagnosis-counting count unit that increases the number of diagnosis counting when the diagnosis-counting-increase signal is output from the increase determination unit of the diagnosis count increase determination unit.

17. The battery pack of claim 16, wherein the cell balancing mode change determination unit determines that the cell balancing mode needs to be changed and outputs a mode change signal, when the number of diagnosis counting counted by the number-of-diagnosis-counting count unit is less than or equal to the reference number of diagnosis counting.

18. The battery pack of claim 17, wherein the cell balancing control unit comprises:
a switch control unit that turns on the cell balancing switch of the cell balancing unit with the initial duty ratio when the balancing start signal is output from the necessity determination unit of the cell balancing necessity determination unit; and
a cell balancing mode setting unit that sets the cell balancing mode to the initial cell balancing mode when the balancing start signal is output from the necessity determination unit of the cell balancing necessity determination unit.

19. The battery pack of claim 18, wherein the switch control unit of the cell balancing control unit turns on the cell balancing switch with the duty ratio of the cell balancing switch set to be increased by a predetermined range when the duty ratio change signal is output from the change determination unit of the duty ratio change determination unit, and
turns off the cell balancing switch when the balancing end signal is output from the necessity determination unit of the cell balancing necessity determination unit.

20. The battery pack of claim 18, wherein the cell balancing mode setting unit of the cell balancing control unit makes setting by changing the cell balancing mode when the mode change signal is output from the cell balancing mode change determination unit.

21. The battery pack of claim 20, wherein the cell balancing mode is one of a charging mode, a standby mode, and a discharging mode, and
changing of the cell balancing mode is set in an order of the charging mode, the standby mode, and the discharging mode.
